(19) United States
(12) Patent Application Publication
(10) Pub. No.: US 2010/0033022 A1
(43) Pub. Date: Feb. 11, 2010

(54) SIGNAL COUPLER

(75) Inventor: Hisami Saitou, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/482,566

(22) Filed: Jun. 11, 2009

(30) Foreign Application Priority Data
Aug. 6, 2008 (JP) 2008-203296

(51) Int. Cl. H01F 38/14

(52) U.S. Cl. 307/104

(57) ABSTRACT

According to an aspect of the present invention, there is provided a signal coupler including, a first coil being formed over a semiconductor substrate, the first coil including a first pad-pair and a first metal wiring, the first pad-pair including two first pads, the first metal wiring being perpendicularly configured as a half-loop over the semiconductor substrate, both ends of the first metal wiring being bonded to each of the first pad, respectively, an input circuit being configured in the semiconductor substrate and providing electrical current corresponding to an input signal to the first metal wiring, a second coil being opposed to the first coil and formed over the semiconductor substrate, the second coil including a second pad-pair and a second metal wiring, the second pad-pair including two second pads, the second metal wiring being perpendicularly configured as the half-loop over the semiconductor substrate, both ends of the second metal wiring being bonded to each of the second pad, respectively, the second coil detecting magnetic field variation generated in the vicinity of the first coil and generating an output electrical current corresponding to the magnetic field variation, and an output circuit being configured in the semiconductor substrate and outputting an output signal corresponding to the output electrical current.

### CROSS REFERENCE TO RELATED APPLICATION

This application is based upon and claims the benefit of priority from the prior Japanese Patent Application No. JP2008-203296, filed Aug. 6, 2008; the entire contents of which are incorporated herein by reference.

### FIELD OF THE INVENTION

The present invention relates to a signal coupler.

### DESCRIPTION OF THE BACKGROUND

Conventionally, a photo coupler having a light emitting element and a light receiving element has been known as a signal coupler sending and receiving electrical signals. The light emitting element in the photo coupler transforms an electrical signal into an optical signal, the electrical signal being output from an IC-chip for transmitting signals. The light receiving element in the photo coupler receives the optical signal and transforms the optical signal into an electrical signal, and an IC-chip for receiving signals receives the electrical signal and further outputs the electrical signal.

However, the light emitting element has a problem that light emitting efficiency is decreased by a phenomenon of interannual change. Therefore, light intensity is decreased so that the signal coupler with high reliability and long lifetime has not been obtained.

For improvement of the degradation, a magnetic coupler, for example, is disclosed in Japanese Patent Publication (Kokai) No. 2006-339257 as a signal coupler having less characteristic variation by the phenomenon of interannual change. The magnetic coupler has been known as a signal coupler communicating signals by a transfer coil.

A primary coil transmitting an electrical signal and a secondary coil receiving the electrical signal are disposed as opposed each other to be electrically isolated in the magnetic coupler disclosed in Japanese Patent Publication (Kokai) No. 2006-339257. Each coil is constituted with conductive wirings suitably formed on prescribed substrates in a plurality of insulating substrates being stacked.

However, plane coils in the magnetic coupler disclosed in Japanese Patent Publication (Kokai) No. 2006-339257 are closely disposed, accordingly, space distances between the plane-coils can not be designed so long. Therefore, the magnetic coupler has problems that obtaining higher dielectric voltage is difficult and parasitic capacitance is larger. As a result, the magnetic coupler easily receives an influence of noise.

Furthermore, for example, a transfer coil including a metal wiring connecting terminals between wiring patterns disclosed in Japanese Patent Publication (Kokai) No. 2001-167941.

The transfer coil disclosed in Japanese Patent Publication (Kokai) No. 2001-167941 includes a circuit substrate with prescribed wiring patterns being a portion of coils and a core being based on the wiring pattern to be configured on the circuit substrate. A terminal between the wiring patterns on the circuit substrate is connected with a metal wiring so that the metal wiring is connected to surround the core.

However, a transfer coil disclosed in Japanese Patent Publication (Kokai) No. 2001-167941 is used as a tool for transporting energy such as a DC-DC converter or the like. Accordingly, the transfer coil has a problem not to be available as a small-type.

### SUMMARY OF THE INVENTION

According to an aspect of a present invention, there is provided a signal coupler including, a first coil being formed over a semiconductor substrate, the first coil including a first pad-pair and a first metal wiring, the first pad-pair including two first pads, the first metal wiring being perpendicularly configured as a half-loop over the semiconductor substrate, both ends of the first metal wiring being bonded to each of the first pad, respectively, an input circuit being configured in the semiconductor substrate and providing electrical current corresponding to an input signal to the first metal wiring, a second coil being opposed to the first coil and formed over the semiconductor substrate, the second coil including a second pad-pair and a second metal wiring, the second pad-pair including two second pads, the second metal wiring being perpendicularly configured as the half-loop over the semiconductor substrate, both ends of the second metal wiring being bonded to each of the second pad, respectively, the second coil detecting magnetic field variation generated in the vicinity of the first coil and generating an output electrical current corresponding to the magnetic field variation, and an output circuit being configured in the semiconductor substrate and outputting an output signal corresponding to the output electrical current.

According to another aspect of the invention, there is provided a signal coupler including, a first coil including a plurality of turns, being formed over a semiconductor substrate, and being constituted with a plurality of first pad-pairs and a plurality of first metal wirings, each of the first pad-pairs including two first pads and being configured towards a prescribed direction, each of the first metal wirings being perpendicularly formed over the semiconductor substrate as a half-loop, both ends of the first metal wiring being bonded to the first pads, respectively, an input circuit being configured in the semiconductor substrate, the input circuit providing an electrical current corresponding to an input signal to the first coil, a second coil including a plurality of turns, being opposed to the first coil, being formed over the semiconductor substrate, and being constituted with a plurality of second pad-pairs and a plurality of second metal wirings, each of the second pad-pairs including two second pads and being configured towards the prescribed direction, each of the second metal wirings being perpendicularly formed over the semiconductor substrate as the half-loop, both ends of the second metal wiring being bonded to the second pads, respectively, the second coil detecting magnetic field variation generated in the vicinity of the first coil and generating an output electrical current corresponding to magnetic field variation, and an output circuit being formed in the semiconductor substrate and outputting an output electrical current corresponding to an output signal.

### BRIEF DESCRIPTION OF THE DRAWINGS

FIG. 1 is a perspective view showing a signal coupler according to a first embodiment of the present invention;

FIG. 2 is a cross-sectional view showing the signal coupler according to the first embodiment of the present invention;

FIG. 3 is a perspective view showing a signal coupler according to a second embodiment of the present invention;

FIG. 4A is a perspective view showing a signal coupler according to a third embodiment of the present invention;

FIG. 4B is a schematic view showing an arrangement of pads in the signal coupler according to the third embodiment of the present invention;

FIG. 5A is a perspective view showing a signal coupler according to a fourth embodiment of the present invention;

FIG. 5B is a schematic view showing an arrangement of pads in the signal coupler according to the fourth embodiment of the present invention;

FIG. 6A is a perspective view showing a signal coupler according to a fifth embodiment of the present invention;

FIG. 6B is a schematic view showing an arrangement of pads in the signal coupler according to the fifth embodiment of the present invention;

FIG. 7 is a perspective view showing a signal coupler according to a sixth embodiment of the present invention;

FIG. 8 is a perspective view showing a signal coupler according to a seventh embodiment of the present invention;

FIG. 9 is a perspective view showing a signal coupler according to an eighth embodiment of the present invention.

### DETAILED DESCRIPTION OF THE INVENTION

Embodiments of the present invention will be described below in detail with reference to the drawing mentioned above.

### First Embodiment

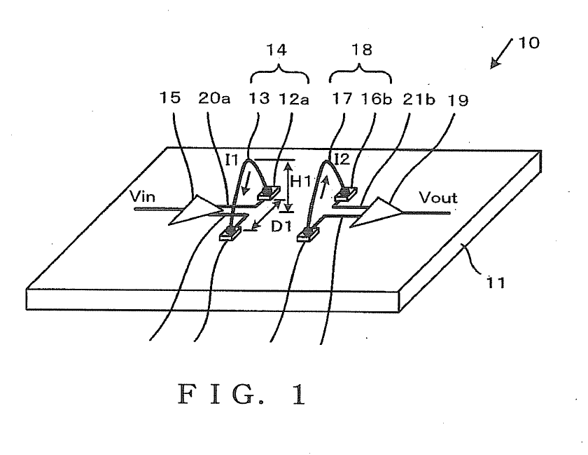

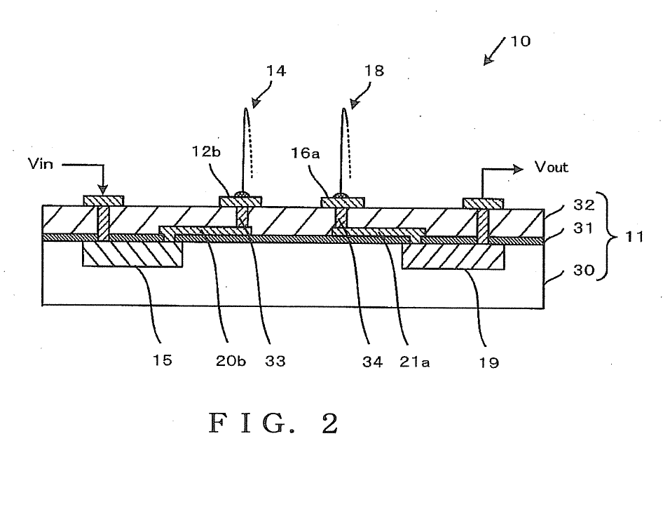

A signal coupler according to a first embodiment of the present invention will be explained using FIG. 1 and FIG. 2. FIG. 1 is a perspective view showing the signal coupler and FIG. 2 is a cross-sectional view showing the signal coupler according to the first embodiment of the present invention, respectively.

As shown in FIG. 1, a signal coupler 10 in this embodiment includes a first coil 14, an input circuit 15, a second coil 18 and an output circuit 19.

The first coil 14 includes a first pad-pair with two first pads 12a and 12b being formed on a semiconductor substrate 11 and a first metal wiring 13 being perpendicularly configured on the semiconductor substrate 11 as a half-loop, both ends of the first metal wiring 13 being bonded to the two first pads 12a and 12b, respectively. The input circuit 15 is formed in the semiconductor substrate 11 and provides an electrical current I₁ corresponding to an input signal Vin input into the input circuit 15.

The second coil 18 includes a second pad-pair with two second pads 16a and 16b being formed on the semiconductor substrate 11 and a second metal wiring 17 being perpendicularly configured as opposed to the first metal wiring 13 on the semiconductor substrate 11 as a half-loop, both ends of the second metal wiring 17 being bonded to the two second pads 16a and 16b, respectively. The second coil 18 is formed on the semiconductor substrate 11 and detects magnetic field variation generated in the vicinity of the first coil 14 so as to output an output signal Vout corresponding to the magnetic field variation to the output circuit 19.

The first metal wiring 13 and the second metal wiring 17, for example, are aluminum wirings, respectively, and are connected to aluminum films of the first pads 12a and 12b, and the second pads 16a and 16b by ultra-sonic bonding, respectively.

When ultra-sonic bonding is performed, for example, a bonding head is moved to pull up the aluminum wiring being longer than the distance between the two pads of the pads-pair so that the first metal wiring 13 and the second metal wiring 17, for example, can be connected to the pads-pair as the half-loop.

The first pads 12a and 12b are connected to the input circuit 15 via wirings 20a and 20b. The second pads 16a and 16b are connected to the output circuit 19 via wirings 21a and 21b.

The input circuit 15 transforms voltage of the input signal Vin being a logic signal into an electrical current and provides the electrical current I, to the first coil 14 as low impedance.

The output circuit 19 amplifies and shapes an output, for example electrical current or voltage, corresponding to the magnetic field variation detected by the second coil 18 and outputs the output signal Vout being a logic signal.

As shown in FIG. 2, the input circuit 15 and the output circuit 19 are monolithically formed to be integrated in a silicon substrate 30.

The wirings 20a and 20b connected to the input circuit 15 and the wirings 21a and 21b connected to the output circuit 19 are formed on a silicon dioxide 31 protecting a surface of the silicon substrate 30.

The first pads 12a and 12b, and the second pads 16a and 16b are formed on a silicon dioxide 32 protecting the wirings 20a,20b,21a and 21b, respectively.

The first pads 12a and 12b are connected to the wirings 20a and 20b through a via-hole 33 passing through the silicon dioxide 32. The second pads 16a and 16b are connected to the wirings 21a and 21b through a via-hole 34 passing through the silicon dioxide 32.

Here, the silicon substrate 30, the silicon dioxides 31 and 32 are wholly corresponding to the semiconductor substrate 11.

Magnetic field is generated by an electrical current I₁ flowing in the first coil 14. The magnetic field passes through in the second coil 18 so that the first coil 14 and the second coil 18 are magnetically coupled, as a result, an electrical current I₂ corresponding to the electrical current I₁ flowing in the first coil 14 flows in the second coil 18 by electromagnetic induction.

When the electrical current I₁ in the first coil 14 is varied, the electrical current I₂ flows in the second coil 18. The electrical current I₂ is proportional to a time-variation ratio of the electrical current I₁. When the electrical current I₁ is constant, no electrical current flows in the second coil 18 as the electrical current I₂.

As well-known, the electrical current I₁ flowed in the first coil 14, the terminal voltage V₁, the electrical current I₂ flowed in the second coil 18 and the terminal voltage V₂ are represented by following equations.

Vₗ=jωL₁I₁+jωMI₂, V₂=jωMI₁+jωL₂I₂

Here, ω is angular frequency where the electrical current I₁ and I₂ are AC, L₁ is self-inductance of the first coil 14, L₂ is self-inductance of the second coil 18 and M is mutual inductance between the first coil 14 and the second coil 18 and is represented by M=k\sqrt{(L₁·L₂)}, where k is coupling coefficient.

As inductance of a solenoid coil with infinite length is proportional to square of turns-number N and radius R and proportional to magnetic permeability μ of an iron core, accordingly, a self-inductance L₁ of the first coil 14 and a self-inductance L₂ of the second coil 18 depend on a distance D1 between the pad-pairs and a height H1 of the coil. The coupling coefficient k depends on the distance between the first coil 14 and the second coil 18.

Accordingly, from view points of detection sensitivity of the magnetic field variation, it is desirable that the distance D1 between the two pads of the pad-pair and the height H1 of the coil become as larger as possible and the distance between the first coil 14 and the second coil 18 becomes as smaller as possible.

In a case that the output circuit 19,for example, receives an output of the second coil 18 at an input amplifier as high impedance, the electrical current I₂ of the second coil 18 is nearly equal to zero. Accordingly, the output voltage V₂ is obtained corresponding to product of the mutual inductance M and the electrical current I₁ flowed in the first coil 14.

As a result, the output signal Vout is obtained corresponding to the input signal Vin. The electrical signal can be transmitted and be received.

As described above, the signal coupler in this embodiment includes the first coil 14 and the second coil 18 being perpendicularly configured as opposed each other on the semiconductor substrate 11, and the input circuit 15 and the output circuit 19 are monolithically formed in the semiconductor substrate 11.

Consequently, an electrical signal can be transmitted and be received by magnetic couple so that a signal coupler having a small-type and higher reliability is obtained.

### Second Embodiment

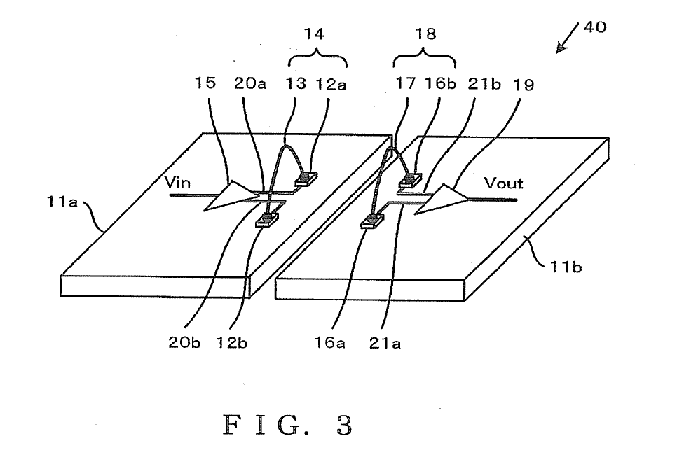

A signal coupler according to a second embodiment of the present invention will be explained using FIG. 3. FIG. 3 is a perspective view showing the signal coupler according to the second embodiment of the present invention.

It is to be noted that the same or similar reference numerals are applied to the same or similar parts and elements throughout the drawings, and the description of the same or similar parts and elements will be omitted or simplified.

The second embodiment is different from the first embodiment at a point, for example, that the first coil and second coil are formed on an individual semiconductor substrate, respectively.

As shown in FIG. 3, the semiconductor substrate 11 is separated into a first semiconductor substrate 11a and a second semiconductor substrate 11b in a signal coupler 40 of this embodiment. The first coil 14 is perpendicularly configured on the first semiconductor'substrate 11a and the input circuit 15 is formed in the first semiconductor substrate 11a. The second coil 18 is perpendicularly configured on the second semiconductor 11b and the output circuit 19 is form in the second semiconductor 11b.

The input circuit 15 is monolithically formed in the first semiconductor substrate 11a. The output circuit 19 is monolithically formed in the second semiconductor substrate 11b.

The first semiconductor substrate 11a and the second semiconductor substrate 11b are configured with electrically isolating so as to be able to independently set up withstanding-voltages of the input circuit 15 and the output circuit 19. Therefore, a constitution of the signal coupler 40 mentioned above is effective in a case of voltage-level having larger difference between the input signal Vin and the output signal Vout.

As mentioned above, the input circuit 15 and the output circuit 19 are formed on the first semiconductor substrate 11a and the second semiconductor substrate 11b in this embodiment, respectively, so that the signal coupler 40 has an advantage that the signal coupler has high withstanding-voltage between the input and the output.

### Third Embodiment

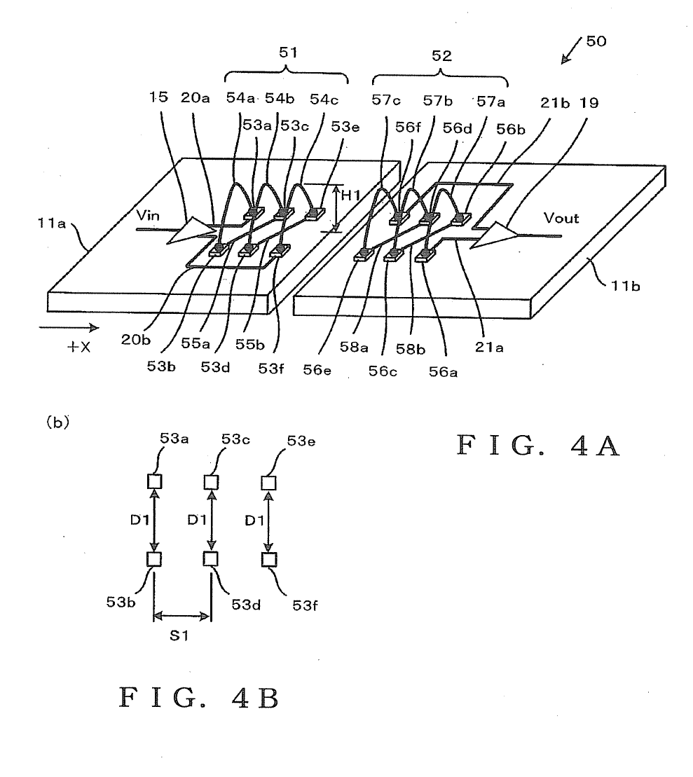

A signal coupler according to a third embodiment of the present invention will be explained using FIGS. 4A and 4B. FIG. 4A is a perspective view showing a signal coupler and FIG. 4B is a schematic view showing an arrangement of pads in the signal coupler according to the third embodiment of the present invention, respectively.

It is to be noted that the same or similar reference numerals are applied to the same or similar parts and elements throughout the drawings, and the description of the same or similar parts and elements will be omitted or simplified.

The third embodiment is different from the second embodiment at a point, for example, that the first coil and the second coil are formed as coils with plural turns.

As shown in FIGS. 4A and 4B, a signal coupler 50 in this embodiment includes a first coil 51, the input circuit 15, a second coil 52 and the output circuit 19. The first coil 51 having three turns is perpendicularly configured on the first semiconductor substrate 11a and the input circuit 15 is formed in the first semiconductor substrate 11a, and the second coil 52 having three turns is perpendicularly configured on the second semiconductor substrate 11b and the output circuit 19 is form in the second semiconductor substrate 11b.

The first coil 51 and the second coil 52 have plural turns, each of turns being arranged in parallel to X-direction in FIG. 4A, respectively. Each of the coils includes a plurality of pad-pairs being arranged in parallel each other, metal wirings being bonded to the pad-pairs, respectively, each of the metal wirings connecting between one pad of the pad-pair and the opposed pad of the adjacent pad-pair in X-direction.

Practically, as shown in FIG. 4B, the first coil 51 includes three pad-pairs having first pads 53a and 53b, first pads 53c and 53d, and first pads 53e and 53f, respectively, first metal wirings 54a, 54b and 54c, and wirings 55a and 55b. Both ends of the first metal wiring 54a are respectively connected to the first pads 53a and 53b disposed with a distance D1 between the two pads of the pad-pair and a pitch S1 between the adjacent pads. As similarly, both ends of the first metal wiring 54b are respectively connected to the first pads 53c and 53d disposed with the distance D1 between the two pads and the pitch S1 between the pad-pairs. Further, both ends of the first metal wiring 54c are respectively connected to the first pads 53e and 53f disposed with the distance D1 between the two pads and the pitch S1 between the pad-pairs. The wiring 55a is connected between the first pad 53b and the first pad 53c being the opposed pad of the adjacent pad-pair. The wiring 55b is connected between first pad 53d and first pad 53e being the opposed pad of the pad-pair.

In similar fashion, the second coil 52 includes three pad-pairs having second pads 56a and 56b, second pads 56c and 56d, and second pads 56e and 56f, respectively, second metal wirings 57a, 57b and 57c, and wirings 58a and 58b. Both ends of the second metal wiring 57a are respectively connected to the second pads 56a and 56b disposed with the distance D1 between the two pads and the pitch S1 between the pad-pairs. As similarly, the both ends of the second metal wiring 57b is respectively connected to the second pads 56c and 56d disposed with the distance D1 between the two pads and the pitch S1 between the pad-pairs Further, both ends of the first metal wiring 57c are respectively connected to the second pads 56e and 56f disposed with the distance D1 between the two pads and the pitch S1 between the pad-pairs. The wiring 58a is connected between the second pad 56b and the second pad 56c being the opposed pad of the adjacent pad-pair. The wiring 58b connects between the first pad 56d and the second pad 56e being the opposed pad of the adjacent pad-pair. Moreover, heights of the first metal wirings 54a, 54b and 54c, and the second metal wirings 57a, 57b and 57c are H1, respectively.

In this fashion, the first coil 51 is a solenoid coil having three turns so that self-inductance L1 of the coil becomes larger. As similarly, the second coil 52 is a solenoid coil having three turns so that self-inductance L2 of the coil becomes larger.

As a result, mutual inductance M between the first coil 51 and the second coil 52 is increased so that detection sensitivity of magnetic field variation can be improved.

As described above, the first coil 51 and the second coil 52 are formed as solenoid coils having three turns, respectively, so that the signal coupler 50 in this embodiment has an advantage of improvement from detection sensitivity of magnetic field variation.

Here, the first coil 51 and the second coil 52 are formed as the solenoid coils having three turns, respectively. However, a number of the coil turns is not restricted and different number of the turns between the first coil 51 and the second coil 52 may be acceptable.

### Fourth Embodiment

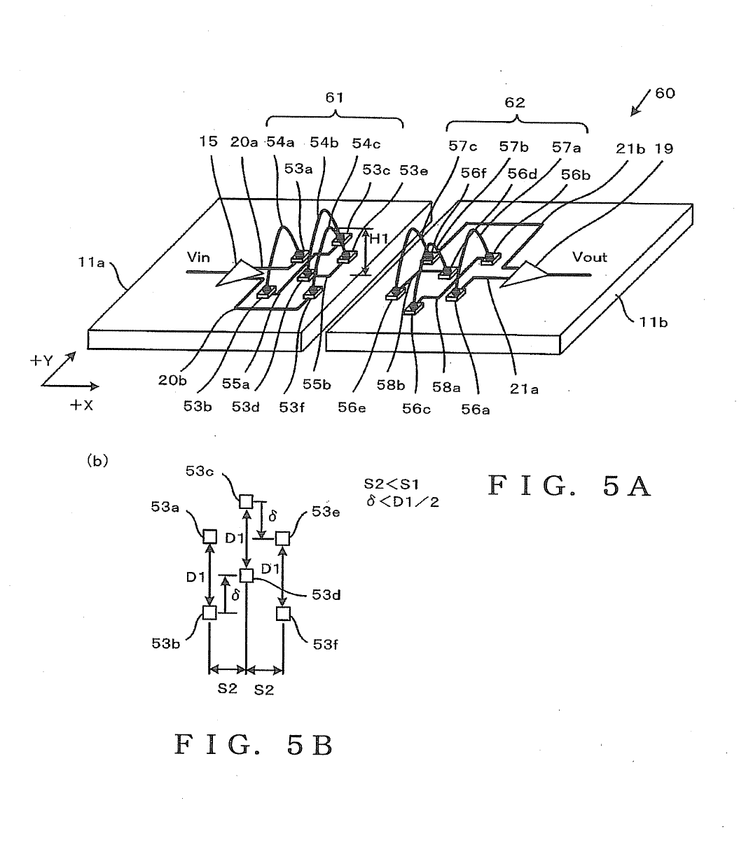

A signal coupler according to a fourth embodiment of the present invention will be explained using FIGS. 5A and 5B. FIG. 5A is a perspective view showing a signal coupler and FIG. 5B is a schematic view showing an arrangement of pads according to the fourth embodiment of the present invention, respectively.

It is to be noted that the same or similar reference numerals are applied to the same or similar parts and elements throughout the drawings, and the description of the same or similar parts and elements will be omitted or simplified. The fourth embodiment is different from the third embodiment at a point, for example, that pad-pairs are alternately configured in parallel.

As shown in FIGS. 4A and 4B, a signal coupler 60 in this embodiment includes a first coil 61, the input circuit 15, a second coil 62 and the output circuit 19. The first coil 61 having three turns is perpendicularly configured on the first semiconductor substrate 11a and the input circuit 15 is form in the first semiconductor substrate 11a, and the second coil 62 having three turns is perpendicularly configured on the second semiconductor substrate 11b and the output circuit 19 is form in the second semiconductor substrate 11b.

The first coil 61 and the second coil 62 have plural turns, each of turns being arranged in parallel to X-direction as shown in FIG. 5A, respectively. Each of the coils includes a plurality of pad-pairs being alternately arranged in parallel each other, metal wirings being bonded to the pad-pairs, respectively, each of the metal wirings connecting between one pad of a pad-pair and the opposed pad of the adjacent pad-pair in X-direction.

Actually, as shown in FIG. 5B, the first pads 53c and 53d are configured with a shift of δ to +Y-direction for the first pads 53a and 53b in the first coil 61. The first pads 53e and 53f are configured with the shift of δ to −Y-direction for the first pads 53c and 53d.

In similar fashion, the second pads 56c and 56d are configured with the shift of δ to −Y-direction for the second pads 56a and,56b in the second coil 62. The second pads 56e and 56f are configured with the shift of δ to +Y-direction for the second pads 56c and 56d.

In this structure, a distance S2 between adjacent first pads as shown in FIG. 5 can be set smaller than the distance S1 between adjacent first pads as shown in FIG. 4. Namely, ultra-sonic bonding is easily performed without being obstructed by the adjacent first pads 53c and 53d when the metal wiring 54a is bonded to the first pads 53a and 53b.

The sizes of the first coil 61 and the second coil 62 to X-direction becomes smaller, accordingly, the signal coupler 60 can be formed as a small-type.

With the effect mentioned above, as self-inductances L1 and L2 of are increased with decreasing a pitch between the first coil 61 and second coil 62, a mutual inductance M between the first coil 61 and the second coil 62 is increased so that detection-sensitivity of magnetic field variation can be improved.

Furthermore, in a case without changing the sizes of the first coil 61 and second coil 62, the turns of the first coil 61 and second coil 62 can be increased, as a result, the self-inductances of the first coil 61 and second coil 62 becomes larger so that detection-sensitivity of the magnetic field variation can be further improved.

The distance δ sifting an adjacent pad-pair to Y-direction may be as smaller as possible in a range without obstruction for ultra-sonic bonding. The smaller distance leads to smaller turbulence in a distribution of magnetic field being generated in the coil.

Furthermore, a maximum value of the distance δ is a half of the distance D1 between the pad-pairs due to geometric arrangement.

As described above, the plurality of pad-pairs are alternately configured in parallel in the signal coupler 60 of this embodiment.

As a result, the distance between the adjacent pads can be smaller from S1 to S2 without obstructing ultra-sonic bonding so that the signal coupler 60 has an advantage to be formed as a small type.

Furthermore, the signal coupler 60 has an advantage that detection-sensitivity of magnetic field variation is improved.

### Fifth Embodiment

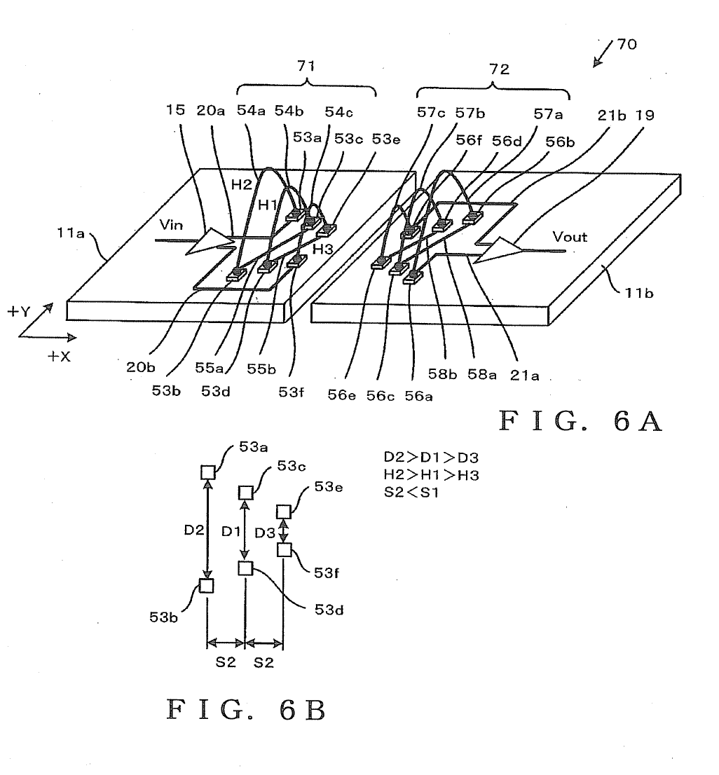

A signal coupler according to a fifth embodiment of the present invention will be explained using FIGS. 6A and 6B. FIG. 6A is a perspective view showing a signal coupler and FIG. 6B is a schematic view showing an arrangement of pads in the signal coupler according to the fifth embodiment of the present invention, respectively.

It is to be noted that the same or similar reference numerals are applied to the same or similar parts and elements throughout the drawings, and the description of the same or similar parts and elements will be omitted or simplified.

The fifth embodiment is different from the third embodiment at a point, for example, that a distance between two pads of a pad-pair is different from a distance between the two pads of the adjacent pad-pair.

As shown in FIGS. 6A and 6B, a signal coupler 60 in this embodiment includes a first coil 71, the input circuit 15, a second coil 72 and the output circuit 19. The first coil 71 having three turns is perpendicularly configured on the first semiconductor substrate 11a and the input circuit 15 is form in the first semiconductor substrate 11a, and the second coil 72 having three turns is perpendicularly configured on the second semiconductor substrate 11b and the output circuit.19 is form in the second semiconductor substrate 11b.

The first coil 71 and the second coil 72 respectively have plural turns, each of turns being arranged in parallel. Each of the coils includes a plurality of pad-pairs, each of the pad-pairs having one distance between the two pads being different from another distance between the two pads of the adjacent pad-pair, metal wirings being bonded to the pad-pairs, each of the metal wirings connecting between one pad of a pad-pair and the opposed pad of the adjacent pad-pair in X-direction.

Practically, a relation between adjacent first pads, for example, the first pads 53a and 53b and the first pads 53c and 53d is shown in FIG. 6B. Namely, a distance D2 between the first pads 53a and 53b is different from a distance D1 between the first pads 53c and 53d. The distance D2 is designed to be larger than the distance D1.

Furthermore, the relation between adjacent first pads, for example, the first pads 53c and 53d and the first pads 53e and 53f is shown in FIG. 6B. Namely, a distance D3 between the first pads 53e and 53f is different from the distance D1 between the first pads 53c and 53d. The distance D3 is designed to be smaller than the distance D2.

In similar fashion, a relation between adjacent second pads, for example, the second pads 56a and 56b and the second pads 56c and 56d is shown in FIG. 6B. Namely, a distance D2 between the second pads 56a and 56b is different from a distance D1 between the second pads 56c and 56d. The distance D2 is designed to be larger than the distance D1.

Furthermore, the relation between adjacent second pads, for example, the second pads 56c and 56d and the second pads 56e and 56f is shown in FIG. 6B. Namely, a distance D3 between the second pads 56e and 56f is different from the distance D1 between the second pads 56c and 56d. The distance D3 is designed to be smaller than the distance D2.

A height of each metal wiring is designed to corresponding to the distance in each pad-pair so that the half loops have similarity each other. In the first coil 71, a height H3 of the first metal wiring 54c, a height H1 of the first metal wiring 54b and a height H2 of the first metal wiring 54a are arranged to be larger corresponding to the distances D3, D1 and D2 in order.

In similar fashion, in the second coil 72, a height H3 of the second metal wiring 57c, a height H1 of the second metal wiring 57b and the height H2 the second metal wiring 57a are arranged to be larger corresponding to the distances D3, D1 and D2 in order.

In this structure, a distance S2 between the adjacent first pads as shown in FIG. 5 can be designed as smaller than the distance S1 between the adjacent first pads as shown in FIG. 4. Namely, ultra-sonic bonding is easily performed without being obstructed by the adjacent first pads 53c and 53d when the metal wiring 54a is bonded to the first pads 53a and 53b.

The sizes of the first coil 71 and the second coil 72 to X-direction becomes smaller, accordingly, the signal coupler 70 can be formed as a small-type.

Moreover, the height of each half-loop coil is gradually decreased towards the opposed coils so that divergence of magnetic field can be suppressed.

As described above, the plurality of the pad-pairs are configured in parallel in the signal coupler 70 of this embodiment and the distance between the two pads of the pad-pair is different from the adjacent distance of the two pads in the adjacent pad-pair to be gradually changed.

As a result, the distance between the adjacent pads can be smaller for the distance S2 without obstructing ultra-sonic bonding so that the signal coupler 70 has an advantage to be formed as a small-type.

Furthermore, the signal coupler 70 has an advantage that divergence of magnetic field can be suppressed.

In this embodiment, it is described a case of the distance between the two pads of the pad-pair being gradually decreased or increased. However, it may be available in a case of the distance between the two pads of the pad-pair being different and alternately being configured.

### Sixth Embodiment

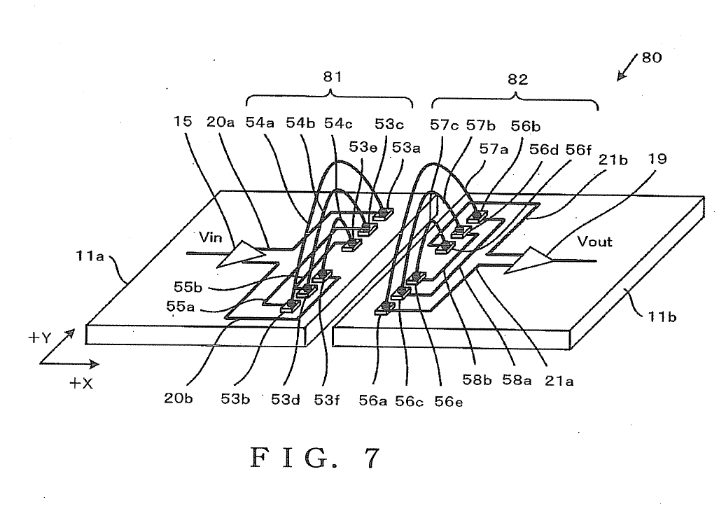

A signal coupler according to a sixth embodiment of the present invention will be explained using FIG. 7. FIG. 7 is a perspective view showing a signal coupler according to the sixth embodiment of the present invention. It is to be noted that the same or similar reference numerals are applied to the same or similar parts and elements throughout the drawings, and the description of the same or similar parts and elements will be omitted or simplified.

The sixth embodiment is different from the third embodiment at a point, for example, that pad-pairs are arranged in a linearly-nested manner.

As shown in FIG. 7, a signal coupler 80 in this embodiment includes a first coil 81, the input circuit 15, a second coil 82 and the output circuit 19. The first coil 81 having three turns is perpendicularly configured on the first semiconductor substrate 11a and the input circuit 15 is form in the first semiconductor substrate 11a, and the second coil 82 having three turns is perpendicularly configured on the second semiconductor substrate 11b and the output circuit 19 is form in the second semiconductor substrate 11b.

The first coil 81 and the second coil 82 have plural turns, each of turns is arranged in parallel. Each of the coils includes a plurality of pad-pairs, each of the pad-pairs is arranged in a linearly-nested manner, metal wirings being bonded to the pad-pairs, each of the metal wirings connecting between one pad of a pad-pair and the opposed pad of the adjacent pad-pair in X-direction.

Practically, the first pads 53c and 53d are configured inside the first pads 53a and 53b, and the first pads 53e and 53f are configured inside the first pads 53c and 53d.

In similar fashion, the second pads 56c and 56d are configured inside the second pads 56a and 56b, and the second pads 56e and 56f are configured inside the second pads 56c and 56d.

A height of each metal wiring is designed corresponding to the distance in each pad-pair so that the half loops are similarity each other.

In this structure, the first coil 81 and the second coil 82 having a half-whorled pattern are obtained, accordingly, a length of the coil in X-direction can be smaller.

As described above, the plurality of pad-pairs are configured in the linearly-nested manner in the signal coupler 80 of this embodiment and the first coil 81 and the second coil 82 having the half-whorled pattern are obtained.

As a result, the signal coupler 80 has an advantage to be smaller on a thickness of the coil in perpendicular direction to the substrate. The structure is a suitable as a small-type signal coupler with a smaller width than a smaller depth and a smaller height.

### Seventh Embodiment

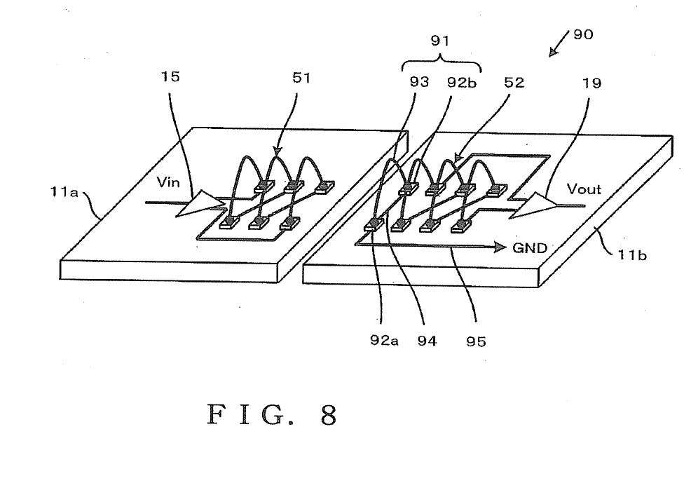

A signal coupler according to a seventh embodiment of the present invention will be explained using FIG. 8. FIG. 8 is a perspective view showing a signal coupler according to the sixth embodiment of the present invention.

It is to be noted that the same or similar reference numerals are applied to the same or similar parts and elements throughout the drawings, and the description of the same or similar parts and elements will be omitted or simplified.

The seventh embodiment is different from the third embodiment at a point, for example, that a third coil is disposed between the first coil and the second coil.

As shown in FIG. 8, a signal coupler 90 in this embodiment includes a third coil 91, the first coil 51, the input circuit 15, the second coil 52 and the output circuit 19. The first coil 51 having three turns is perpendicularly configured on the first semiconductor substrate 11a and the input circuit 15 is form in the first semiconductor substrate 11a, and the second coil 52 having three turns is perpendicularly configured on the second semiconductor substrate 11b and the output circuit 19 is form in the second semiconductor substrate 11b.

The third coil 91 includes a third pad-pair having two third pads 92a and 92b, a third metal wiring 93 being connected to the two third pads 92a and 92b, a wiring 94 connected between the two third pads 92a and 92b, and a wiring 95 connecting the third pad 92a to standard potential GND.

A parasitic capacitance is generated between the first coil 51 and the second coil 52. The first coil 51 and the second coil can be magnetically shielded by arranging the third coil 91 connected to standard potential GND between the first coil 51 and the second coil 53.

In this structure, the signal coupler 90 can suppress that noise penetrates into the first coil 51 and the second coil 52 through the parasitic capacitance. Accordingly, the signal coupler 90 can be stably operated to increase reliability.

As described above, the third coil 91 connected to standard potential GND is configured between the first coil 51 and the second coil 52 in the signal coupler 90 of this embodiment, accordingly, the signal coupler 90 has an advantage to suppress that the noise penetrates into the first coil 51 and the second coil 52 through the parasitic capacitance to increase reliability.

It is explained on a case that the third coil 91 is configured on the second semiconductor substrate 11b. However, the third coil 91 may be configured on the first semiconductor substrate 11. Furthermore, it is explained on a case that standard potential is earth potential. However, a bias voltage may be suitably applied.

### Eighth Embodiment

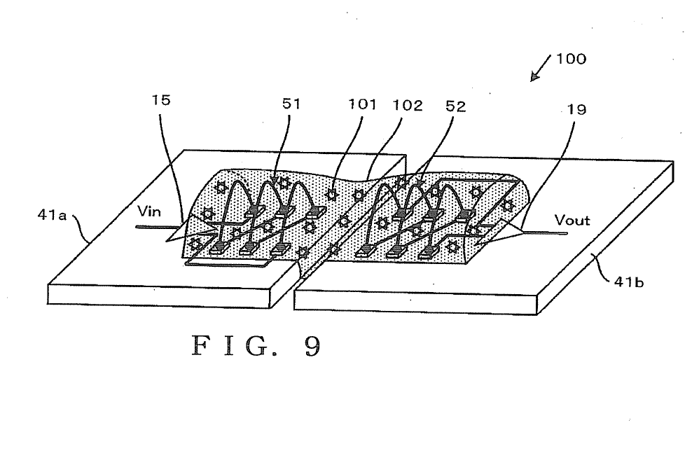

A signal coupler according to an eighth embodiment of the present invention will be explained using FIG. 9. FIG. 9 is a perspective view showing a signal coupler according to the eighth embodiment of the present invention.

It is to be noted that the same or similar reference numerals are applied to the same or similar parts and elements throughout the drawings, and the description of the same or similar parts and elements will be omitted or simplified.

The eighth embodiment is different from the third embodiment at a point, for example, that the first coil and the second coil are covered with a resin containing a magnetic powder.

As shown in FIG. 9, a signal coupler 100 in this embodiment includes the first coil 51, the input circuit 15, the second coil 52 and the output circuit 19. The first coil 51 having three turns is perpendicularly configured on a first semiconductor substrate 41a and the input circuit 15 is form in the first semiconductor substrate 41a, and the second coil 52 having three turns is perpendicularly configured on a second semiconductor substrate 41b and the output circuit 19 is form in the second semiconductor substrate 41b. The first coil 51 and the second coil 52 are integrally-molded by a resin 102 containing magnetic powders 101.

The magnetic powders 101 are constituted with ferrite, for example, and the resin 102 is a transparent silicone resin for encapsulating, for example.

Self-inductance L1 of the first coil, self-inductance L2 of the second coil and mutual inductance M between the first coil and the second coil are increased corresponding to magnetic permeability μ of the magnetic powders 101 so that detection sensitivity of the magnetic field variation can be increased.

As a content of the magnetic powders 101 are higher, magnetic field of the first coil 51 and the second coil 52 can be higher. However, the content of the magnetic powders 101 may be suitably determined corresponding to a size of the magnetic powders 101, viscosity of the resin 102 or the like, so that the magnetic powders 101 in the resin 102 distribute as uniformly as possible.

Moreover, as detection sensitivity in constant variation of magnetic field is also obtained in the first coil 51 and the second coil 52 being formed as smaller, the signal coupler can be formed as a small-type.

As described above, the first coil 51 and the second coil 52 are integrally-molded by the resin 102 containing the magnetic powders 101 in the signal coupler 100 of this embodiment.

As a result, mutual inductance M between the first coil 51 and the second coil 52 is increased. Therefore, the signal coupler has advantages of improvement on detection sensitivity of the magnetic field variation and a size to be smaller, for example.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

What is claimed is:

1. A signal coupler comprising;
a first coil being formed over a semiconductor substrate, the first coil including a first pad-pair and a first metal wiring, the first pad-pair including two first pads, the first metal wiring being perpendicularly configured as a half-loop over the semiconductor substrate, both ends of the first metal wiring being bonded to each of the first pad, respectively;
an input circuit being configured in the semiconductor substrate and providing electrical current corresponding to an input signal to the first metal wiring;
a second coil being opposed to the first coil and formed over the semiconductor substrate, the second coil including a second pad-pair and a second metal wiring, the second pad-pair including two second pads, the second metal wiring being perpendicularly configured as the half-loop over the semiconductor substrate, both ends of the second metal wiring being bonded to each of the second pad, respectively, the second coil detecting magnetic field variation generated in the vicinity of the first coil and generating an output electrical current corresponding to the magnetic field variation; and
an output circuit being configured in the semiconductor substrate and outputting an output signal corresponding to the output electrical current.

2. The signal coupler of claim 1, wherein
an insulator is formed between the semiconductor substrate and the first coil and the second coil, the input circuit and the output circuit is covered with the insulator, the first coil and the input circuit are connected each other through a first via-hole formed in the insulator, and the second coil and the output circuit are connected each other through a second via-hole formed in the insulator.

3. The signal coupler of claim 1, wherein
the semiconductor substrate is constituted with a first semiconductor substrate and a second semiconductor substrate, the first coil is configured over the first semiconductor substrate, the input circuit is configured in the first semiconductor substrate, the second coil is configured over the second semiconductor substrate, and the output circuit is configured in the second semiconductor substrate.

4. The signal coupler of claim 1, wherein
the first coil includes a plurality of the first pad-pairs and a plurality of the first metal wirings or the second coil includes a plurality of the second pad-pairs and a plurality of the second metal wirings.

5. A signal coupler comprising;
a first coil including a plurality of turns, being formed over a semiconductor substrate, and being constituted with a plurality of first pad-pairs and a plurality of first metal wirings, each of the first pad-pairs including two first pads and being configured towards a prescribed direction, each of the first metal wirings being perpendicularly formed over the semiconductor substrate as a half-loop, both ends of the first metal wiring being bonded to the first pads, respectively;
an input circuit being configured in the semiconductor substrate, the input circuit providing an electrical current corresponding to an input signal to the first coil;
a second coil including a plurality of turns, being opposed to the first coil, being formed over the semiconductor substrate, and being constituted with a plurality of second pad-pairs and a plurality of second metal wirings, each of the second pad-pairs including two second pads and being configured towards the prescribed direction, each of the second metal wirings being perpendicularly formed over the semiconductor substrate as the half-loop, both ends of the second metal wiring being bonded to the second pads, respectively, the second coil detecting magnetic field variation generated in the vicinity of the first coil and generating an output electrical current corresponding to magnetic field variation; and
an output circuit being formed in the semiconductor substrate and outputting an output electrical current corresponding to an output signal.

6. The signal coupler of claim 5, wherein
an insulator is formed between the semiconductor substrate and the first coil and the second coil are formed on the insulator, the input circuit and the output circuit is covered with the insulator, the first coil and the input circuit are connected each other through a first via-hole formed in the insulator, and the second coil and the output circuit are connected each other through a second via-hole formed in the insulator.

7. The signal coupler of claim 5, wherein
the semiconductor substrate is constituted with a first semiconductor substrate and a second semiconductor substrate, the first coil is configured over the first semiconductor substrate, the input circuit is configured in the first semiconductor substrate, the second coil is configured over the second semiconductor substrate and the output circuit is configured in the second semiconductor substrate.

8. The signal coupler of claim 5, wherein
one first pad of each first pad-pair and the other first pad of each first pad-pair are arranged with align perpendicular to the first pad-pairs, respectively, and/or one second pad of the second pad-pair and the other second pad of the second pad are arranged with align perpendicular to the second pad-pairs, respectively.

9. The signal coupler of claim 5, wherein
the plurality of the first pad-pairs are arranged with a prescribed direction in parallel each other and/or the plurality of second pad-pairs are arranged with a prescribed direction in parallel each other.

10. The signal coupler of claim 9, wherein
a first distance of each first pad-pair is equal each other and/or a second distance of each second pad-pair is equal each other.

11. The signal coupler of claim 9, wherein
one first pad of each first pad-pair and the other first pad of each first pad-pair are arranged with align perpendicular to the first pad-pairs, respectively, and/or one second pad of the second pad-pair and the other second pad f the second pad-pair are perpendicularly arranged with align perpendicular to the second pad-pairs, respectively.

12. The signal coupler of claim 10, wherein
one first pad of the first pad-pair and the other first pad of the first pad-pair are alternately arranged perpendicular to the prescribed direction, and/or one second pad of the second pad-pair and the other second pad of the second pad-pair are alternately arranged perpendicular to the prescribed direction.

13. The signal coupler of claim 9, wherein
the plurality of the first metal wirings are arranged each other in parallel and/or the plurality of the second metal wirings are arranged each other in parallel.

14. The signal coupler of claim 13, wherein
height of each first metal wiring is equal each other and/or height of each second metal wiring is equal each other.

15. The signal coupler of claim 13, wherein
each height of the first metal wirings is different each other and/or each height of the second metal wirings is different each other.

16. The signal coupler of claim 15, wherein
each height of the first metal wirings is decreased to a second coil direction in order and/or each height of the second metal wirings is decreased to a first coil direction in order.

17. The signal coupler of claim 13, wherein
the half-loop formed by each first metal wiring is similar each other and/or the half-loop formed by each second metal wiring is similar each other.

18. The signal coupler of claim 9, wherein
the plurality of first pad-pairs are linearly arranged towards the prescribed direction and each first pad of the first pad-pair is arranged from inside to outside in order, and each height of the first metal wirings is different each other, the height is increased from inside to outside in order and/or the plurality of second pad-pairs are linearly arranged towards the prescribed direction and each second pad of the second pad-pair is arranged from inside to outside in order, and each height of the second metal wirings is different each other, the height is increased from inside to outside in order.

19. The signal coupler of claim 5, further comprising;
a third coil being configured between the first coil and the second coil and opposed to the first coil and the second coil over the semiconductor substrate, the third coil including a third pad-pair and a third metal wiring, the third pad-pair including two third pads, the third metal wiring being perpendicularly configured over the semiconductor substrate as the half-loop, both ends of the third metal wiring being bonded to each of the third pads, respectively.

20. The signal coupler of claim 5, further comprising;
the first coil and the second coil are covered with isolative resin containing a magnetic material.
